(19) United States
(12) Patent Application Publication
(10) Pub. No.: US 2026/0173905 A1
(43) Pub. Date: Jun. 18, 2026

(54) INTEGRATED VOLTAGE REGULATOR IN AN INTERPOSER

(71) Applicant: International Business Machines Corporation, Armonk, NY (US)

(72) Inventors: Mukta Ghate Farooq, HOPEWELL JCT, NY (US); John Knickerbocker, Monroe, NY (US); John W Golz, Hopewell Junction, NY (US); Todd Edward Takken, Brewster, NY (US); Keiji Matsumoto, Yokohama-shi (JP)

(21) Appl. No.: 18/981,460

(22) Filed: Dec. 14, 2024

(51) Int. Cl. H01L 23/538; H01L 21/48; H01L 23/373; H01L 25/18; H10D 1/20; H10D 1/68

(52) U.S. Cl. CPC H10W 70/611; H10D 1/20; H10D 1/68; H10W 70/093; H10W 70/095; H10W 90/00; H10W 90/401; H10W 40/255

(57) ABSTRACT

A semiconductor structure includes one or more integrated circuits (ICs), a wiring layer coupled to the one or more ICs, an input power source, and a substrate located between the wiring layer and the input power source. The substrate having a first side coupled to the input power source, a second side coupled to the wiring layer, an integrated voltage regulator (IVR) located at the first side of the substrate, and a first through-silicon-via (TSV) coupled to the IVR and extending through the substrate and into the wiring layer.

### BACKGROUND

The present disclosure generally relates to the fabrication of integrated circuits, semiconductors, and the like and, more particularly, to various methods of forming an integrated voltage regulator in an interposer and the resulting device.

Previously, voltage regulators were typically located on multilayer boards and were electrically coupled to an integrated circuit. In some cases, to increase efficiency and conserve space, voltage regulators have been integrated into the structure of semiconductors. Passive devices, such as inductors and capacitors and/or stacked capacitors, have also been integrated into the structure of the semiconductor and electrically coupled to integrated voltage regulators (IVRs), further reducing the footprint of the circuitry.

With an addition of integrated devices, such as IVRs, inductors, capacitors and/or integrated stacked capacitors (ISCs), and the like, comes an increase in the significant number and length of interconnections between devices and between devices and wiring layers of the integrated circuit, semiconductor devices, and the like, as the number of devices increases. When the number and length of interconnections increase, both circuit resistance-capacitance (RC) delay and power consumption increase. Along with advancements in technology comes a constant demand for reductions in footprint of such circuitry and increased power efficiency of the voltage regulator, and thus improved functionality of integrated circuits, semiconductor devices, and the like.

### BRIEF SUMMARY

Principles of the invention provide techniques for an integrated voltage regulator in an interposer. In one aspect, an exemplary semiconductor structure includes one or more integrated circuits (ICs), a wiring layer coupled to the one or more ICs, an input power source, and a substrate located between the wiring layer and the input power source. The substrate having a first side coupled to the input power source, a second side coupled to the wiring layer, an integrated voltage regulator (IVR) located at the first side of the substrate, and a first through-silicon-via (TSV) coupled to the IVR and extending through the substrate and into the wiring layer.

Another aspect provides an exemplary method for forming a semiconductor structure includes forming, at a first side of a substrate, an integrated voltage regulator (IVR); forming, proximate to the IVR, first through-silicon-vias (TSVs) in the substrate; forming, on the first side of the substrate, a dielectric layer including an electrical connector; attaching electrical conductors to the dielectric layer, in which the electrical connector in the dielectric layer electrically connects the electrical conductors to the substrate; bonding a temporary carrier to the electrical conductors, flipping over the substrate and the temporary carrier, and recessing a second side of the substrate, exposing the first TSVs; forming, on the recessed second side of the substrate, a wiring layer and a redistribution layer (RDL); extending the first TSVs from the second side of the recessed substrate through the wiring layer; forming a capacitor in the wiring layer; joining to the wiring layer one or more integrated circuits (ICs); removing the temporary carrier; and joining to the dielectric layer, at the electrical conductors, a input power source.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates an exemplary integrated voltage regulator (IVR) in a substrate, according to aspects of the invention;

FIGS. 2-10 illustrate a method of making an integrated voltage regulator (IVR) in a substrate, according to aspects of the invention;

FIG. 11 illustrates a semiconductor structure with thermal layers, according to aspects of the invention;

FIG. 12 illustrates a schematic diagram of an integrated voltage regulator (IVR) in a substrate, according to aspects of the invention;

FIG. 13 illustrates a computing environment according to an embodiment of the present invention (e.g., for implementing a design process such as that of FIG. 14); and

FIG. 14 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary semiconductor structure 1000 includes one or more integrated circuits (ICs) 1031, a wiring layer 1021 coupled to the one or more ICs 1031, an input power source 1033, and a substrate 1001 located between the wiring layer 1021 and the input power source 1033. The substrate 1001 having a first side 1003 coupled to the input power source 1033, a second side 1005 coupled to the wiring layer 1021, an integrated voltage regulator (IVR) 1007 located at the first side 1003 of the substrate 1001, and a first through-silicon-via (TVS) 1009 coupled to the IVR 1007 and extending through the substrate 1001 and into the wiring layer 1021. Technical benefits include allowing for effective connections between an integrated voltage regulator (IVR) 1007 and a wiring layer 1021 (e.g., back-end-of-line (BEOL) wiring layer), with minimal connections and minimal connection real estate. Further, technical benefits include providing a unidirectional current flow through an inductor.

Optionally, the first TSV 1009 can include a magnetic via having a surrounding magnetic material. The magnetic material can be selected from a group including co-fired ferrite, Lead-Dioxide (PbO₂), Beryllium-Oxide (BeO), Strontium-Oxide (SrO), Cobalt (Co), Manganese (Mn), BeO ferric, SrO ferrite, Cobalt-Oxide (CoO) ferrite, and any combination thereof. Technical benefits of utilizing magnetic material includes an increase in inductance with readily available materials.

In a further option, the semiconductor structure 1000 can include thermal layers 1035 separated by a cooling microchannel 1037, in which the first TSV 1009 extends through the thermal layers 1035 and the cooling microchannel 1037. Technical benefits include dissipation of heat and integration of aspects of the inventio with a variety of device layers such as thermal layers.

Continuing with options, the substrate 1001 can include one or more first TSVs 1009 and at least one of the first TSVs 1009 can include an inductor L1, L2. In some options, the IVR 1007 can be connected to the inductor L1, L2 of the first TSV 1009 by a skim-by-connection. In still other options, the IVR 1007 can be connected to the inductor L1, L2 of the first TSV 1009 by the wiring layer 1021. In still further options, the semiconductor structure 1000 can further include a capacitor 1023 coupled to the inductor L1, L2 of the first TSV 1009. Technical benefits of the first TSV 1009 being coupled or directly attached to the capacitor 1023 includes allowing for a minimal distance between the two.

Continuing further with options, the semiconductor structure 1000 can further include a second TSV 1011 extending through the substrate 1001 into the wiring layer 1021, in which the second TSV 1011 can be a signal TSV. In further options, the second TSV 1011 includes a non-magnetic via including a non-magnetic material. Optionally, the second TSV 1011 can have a coaxial structure. In yet another option, the first TSV 1009 can include a first dielectric and a first metal, the second TSV 1011 can include a second dielectric and a second metal, and the second TSV 1011 can include a thicker dielectric, thinner metal, or both, than the first TSV 1009. Technical benefits of a second TSV 1011 include enabling of signal lines to devices within the semiconductor structure 1000 and external devices in connection with the semiconductor structure 1000.

In still further options, the first dielectric and the second dielectric can be selected from the group including Silicon-Dioxide, Silicon-Nitride, Silicon-Oxynitride, Boron-Nitride, Aluminum-Nitride, Beryllium-Oxide, Diamond-Film, Polymer, and any multilayer combination thereof.

In some options, a diameter of the first TSV 1009 can be greater than a diameter of the second TSV 1011.

Optionally, the wiring layer 1021 and the substrate 1001 can be an interposer 1029. In still further options, the semiconductor structure 1000 can include electrical conductors 1017, in which the interposer 1029 can be coupled to the input power source 1033 by the electrical conductors 1017. Technical benefits of the interposer functionality include ability to connect IC chips, which have fine pitch contacts, above the interposer structure 1029 and a non-integrated circuit (e.g., a passive device) below the interposer structure 1029.

An aspect of an exemplary method of forming a semiconductor structure 1000 includes forming at a first side 1003 of a substrate 1001, an integrated voltage regulator (IVR) 1007; forming, proximate to the IVR 1007, first through-silicon vias (TSVs) 1009 in the substrate 1001; forming, on the first side 1003 of the substrate 1001, a dielectric layer 1015 comprising an electrical connector 1013; attaching electrical conductors 1017 to the dielectric layer 1015, in which the electrical connector 1013 in the dielectric layer 1015 electrically connects the electrical conductors 1017 to the substrate 1001; bonding a temporary carrier 1019 to the electrical conductors 1017, flipping over the substrate 1001 and the temporary carrier 1019, and recessing a second side 1005 of the substrate 1001, exposing the first TSVs 1009; forming, on the recessed second side 1005 of the substrate 1001, a wiring layer 1021 and a redistribution layer (RDL) 1025; extending the first TSVs 1009 from the second side 1005 of the recessed substrate 1001 through the wiring layer 1021; forming a capacitor 1023 in the wiring layer 1021; joining to the wiring layer 1021 one or more integrated circuits (ICs) 1031; removing the temporary carrier 1019; and joining to the dielectric layer 1015, at the electrical conductors 1017, an input power source 1033. Technical benefits include allowing for effective connections between an integrated voltage regulator (IVR) 1007, a capacitor 1023, and a wiring layer 1021 (e.g., back-end-of-line (BEOL) wiring layer), with minimal connections and minimal connection real estate. Further, technical benefits include providing a unidirectional current flow through an inductor.

Optionally, in further aspects, the method of forming the semiconductor structure 1000 can further include forming a second TSV 1011, in which the second TSV 1011 is a signal TSV comprising a thicker dielectric, thinner metal, or both, than the first TSVs 1009 and the first TSVs 1009 are formed with a diameter larger than the second TSV 1011. Technical benefits of a second TSV 1011 can include enabling of signal lines to devices within the semiconductor structure 1000 and external devices in connection with the semiconductor structure 1000.

In a further option, the second TSV 1011 extends from the dielectric layer 1015, through the substrate 1001 and at least partially into the wiring layer 1021 or through the wiring layer 1021 to the RDL 1025.

Continuing with options, the method of forming the semiconductor structure 1000 can further include forming an inductor L1, L2 in each of the first TSVs 1009 and connecting the IVR 1007 to the inductor of a first TSV 1009 with a skim-by-connection on a sidewall of the first TSV 1009 or at the wiring layer 1021. In still further options, the method of forming the semiconductor structure 1000 can further include forming a connection between the capacitor 1023 and the inductor L1, L2 in each of the first TSVs 1009 and forming a connection between the capacitor 1023 and the one or more ICs 1031. Technical benefits of the first TSV 1009 being coupled or directly attached to the capacitor 1023 includes allowing for a minimal distance between the two.

Techniques as disclosed herein can provide substantial beneficial technical effects. Some embodiments may not have these potential advantages and these potential advantages are not necessarily required of all embodiments. By way of example only and without limitation, one or more embodiments can provide one or more of:

Allow for effective connections between an integrated voltage regulator (IVR), an integrated stacked capacitor (ISC), and a wiring layer (e.g., back-end-of-line (BEOL) wiring layer), with a high current carrying capability, minimal connections, minimal connection real estate, and a relatively stable non-varying voltage output:
by building an IVR in a silicon interposer substrate proximate to an input power source from a packaging substrate.
by building a through silicon via (TSV) that includes a magnetic material.
by building an inductor in a TSV.
by building magnetic inductors in TSVs connected to an IVR.
by providing unidirectional current flow through an inductor.
by building a capacitor between an inductor and a voltage output.
by building a thick dielectric, thin metal, and/or coaxial structured signal TSV into a substrate.

One or more embodiments advantageously provide an integrated voltage regulator (IVR) that can provide an increase in power efficiency and stability in a smaller footprint with fewer connections and, thus a smaller device, than previous approaches. Aspects of the invention provide techniques for providing an IVR formed at a first side of a substrate (e.g., interposer substrate), the first side of the substrate being coupled to an input power source (e.g., a package substrate) and located opposite a wiring layer (e.g., back-end-of-line (BEOL) wiring layer) of a semiconductor structure. Aspects of the invention further provide a through silicon via (TSV), including an inductor, used for connection between the IVR, an integrated stacked capacitor (ISC), and the wiring layer of the semiconductor structure. The TSV is capable of carrying current unidirectionally between an input power source and an integrated circuit (IC) coupled to the TSV.

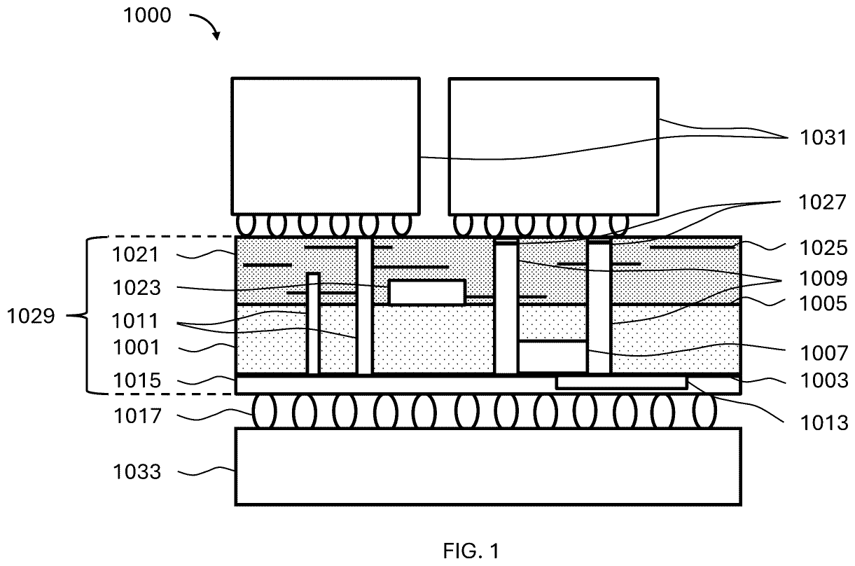

Referring to FIG. 1, an exemplary integrated voltage regulator (IVR) 1007 in a semiconductor structure 1000 is shown. In some embodiments, the semiconductor structure 1000 can be a chip, part of an assembly of chips, or chiplets in 3D or 2.5D. The IVR 1007 can be formed at a first side 1003 of a substrate 1001 during manufacturing of the semiconductor structure 1000. A wiring layer 1021 (e.g., back-end-of-line (BEOL) wiring layer) can be formed at a second side 1005 of the substrate 1001, the second side 1005 of the substrate 1001 being opposite the first side 1003 of the substrate 1001. A redistribution layer (RDL) 1025 can be formed in the wiring layer 1021. A dielectric layer 1015 can be formed on the first side 1003 of the substrate 1001. Accordingly, the dielectric layer 1015 can be opposite the wiring layer 1021. That is, the dielectric layer 1015 can be on the first side 1003 of the substrate 1001, proximate to the IVR 1007, and the wiring layer 1021 can be on the second side 1005 of the substrate 1001. The dielectric layer 1015 can include an electrical connector 1013. Further, the semiconductor structure 1000 can include a capacitor 1023. In some embodiments, the capacitor 1023 can be a metal-insulator-metal (MIM) capacitor, though examples are not so limited. As shown in FIG. 1, the capacitor 1023 can be formed in the wiring layer 1021 of the semiconductor structure 1000, though examples are not so limited and the capacitor 1023 can be formed as an integrated portion of the substrate 1001 or can be embedded within the substrate 1001.

In some embodiments, electrical conductors 1017 can be coupled to the dielectric layer 1015, opposite the substrate 1001. An input power source 1033 (e.g., a packaging substrate) can be electrically connected to the electrical connector 1013 of the dielectric layer 1015 by the electrical conductors 1017. In some nonlimiting examples, the electrical conductors 1017 can be a controlled collapse chip connection (C4), such as a solder ball or bump. In other nonlimiting examples, the electrical conductors 1017 can be bumpless Copper (Cu) bonds.

As further shown in FIG. 1, an integrated circuit (IC) 1031 can be coupled to the wiring layer 1021. In some embodiments, the IC 1031 can be coupled to the wiring layer 1021 via the RDL 1025. In some nonlimiting embodiments, the IC 1031 can be a silicon die system on a chip (SOC). Further, as illustrated in FIG. 1, the semiconductor structure 1000 can include one or more than one IC 1031 (FIG. 1 illustrates two ICs 1031, though a single IC and a quantity of ICs greater than two can be contemplated). Accordingly, the wiring layer 1021 can be located between the substrate 1001 and the IC 1031. In one or more non-limiting exemplary embodiments, aspects of the invention provide an interposer between one or more chips with fine-pitched contacts, above the interposer, and a non-integrated circuit (e.g., passive, or active substrate), below the interposer, as discussed further elsewhere herein.

As further described herein, a first through silicon via (TSV) 1009 can be coupled to the IVR 1007. The first TSV 1009 can extend through the substrate 1001 and into the wiring layer 1021. In some embodiments, the first TSV 1009 can extend through the wiring layer 1021. The first TSV 1009 can be electrically coupled to the input power source 1033, through the electrical connector 1013 of the dielectric layer 1015, and electrically coupled to the IC 1031, through the RDL 1025 and/or wiring layer 1021. In some embodiments, the first TSV 1009 can include a termination 1027 and the first TSV 1009 can be coupled to the IC 1031 at the termination 1027. The capacitor 1023 can be coupled to the first TSV 1009. Some embodiments, as further detailed herein, can include the capacitor 1023 coupled to an inductor of the first TSV 1009 by the wiring layer 1021. Further, as illustrated in FIG. 1, the semiconductor structure 1000 can include one or more than one first TSV 1009 (FIG. 1 illustrates two first TSVs 1009, though a quantity greater than two can be contemplated). In one or more non-limiting exemplary embodiments, as discussed further elsewhere herein, one or more heat sinks (not illustrated to avoid clutter) can be provided above element 1031 and/or below element 1033, and TSVs could provide a conductive path for heat flow.

Some embodiments can include a second TSV 1011. The second TSV 1011 can be a signal TSV that extends through the substrate 1001 and into the wiring layer 1021. That is, the second TSV 1011 can stop in the wiring layer 1021 and signals can be routed by wiring to the IC 1031. Further, in some embodiments, the second TSV 1011 can extend through the wiring layer 1021. Additionally, as illustrated in FIG. 1, the semiconductor structure 1000 can include one or more than one second TSV 1011 (FIG. 1 illustrates two second TSVs 1011, though a quantity greater than two can be contemplated).

Accordingly, the RDL 1025, the wiring layer 1021, the capacitor 1023, the substrate 1001, the first TSV 1009, the second TSV 1011, the IVR 1007, and the dielectric layer 1015 including the electrical connector 1013 can make up an interposer structure 1029. The interposer structure 1029 can be sandwiched between the input power source 1033 and the IC 1031. In some embodiments, an interposer structure 1029 can connect IC chips, which have fine pitch contacts, above the interposer structure 1029 and a non-integrated circuit (e.g., a passive device) below the interposer structure 1029, though examples are not so limited. As used herein, the term “fine pitch” refers to a distance between two contacts that is 100 microns or less. Specifically, a fine pitch set of contacts can typically have a pitch below 75 microns, though examples are not so limited.

Some embodiments can further include one or more heat sinks (not shown). The heat sink(s) can be located above the IC 1031, below the input power source 1033, or both. Through silicon vias with metal (e.g., first TSV 1009, second TSV 1011, etc.) within the semiconductor structure 1000 can conduct heat generated within the semiconductor structure 1000 toward the heat sink, in some instances.

Accordingly, as illustrated in FIG. 1, the IVR 1007 and the input power source 1033 of the semiconductor structure 1000 can be located on the first side 1003 of the substrate 1001. Further the first TSV 1009 can be coupled to the IVR 1007, the capacitor 1023 (e.g., such as a MIM capacitor, though examples are not so limited), and the wiring layer 1021 (e.g., such as a BEOL wiring layer) of the semiconductor structure 1000. Accordingly, current can flow unidirectionally between the input power source 1033 and the IC 1031, through the IVR 1007, the first TSV 1009, the capacitor 1023, and the wiring layer 1021. Technical benefits of such a semiconductor structure 1000 include providing a unidirectional current flow through the first TSV 1009, increasing power distribution and improving power delivery stability within a smaller footprint than previous approaches.

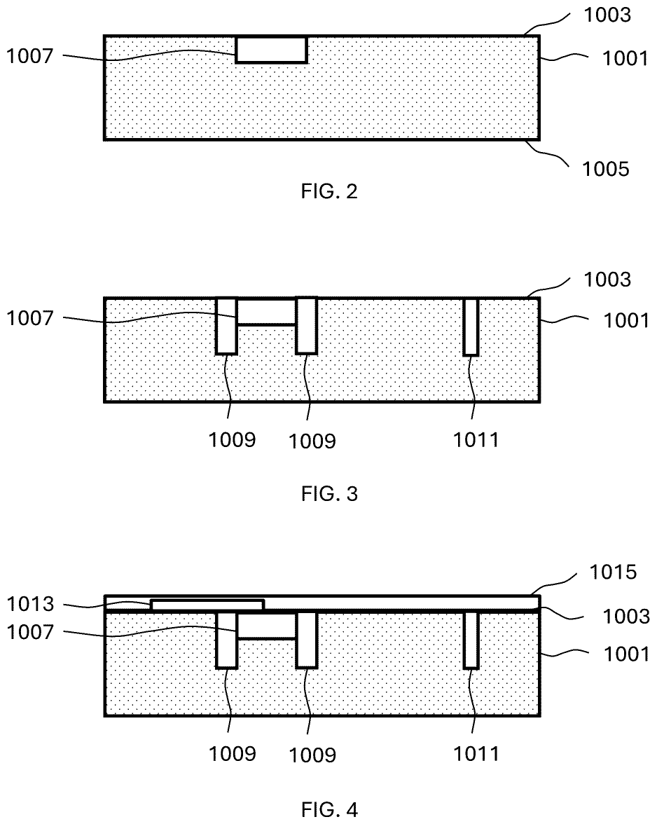

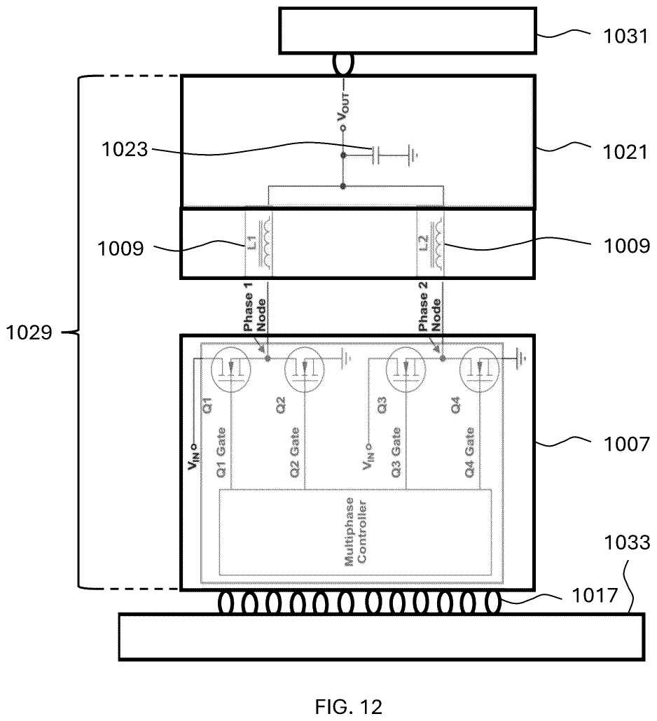

FIGS. 2-10 illustrate an exemplary technique for making and connecting an integrated voltage regulator (IVR) 1007 to a capacitor 1023 and wiring layer 1021 in a semiconductor structure. Referring to FIG. 2, an IVR 1007 can be formed on a first side 1003 of a substrate 1001 during manufacturing of the semiconductor structure. As is further illustrated later in FIG. 12, the IVR 1007 can include multiple devices (such as transistors) used in operation of the IVR 1007.

A first through silicon via (TSV) 1009 can be formed in the substrate 1001, as shown in FIG. 3. As further described herein in connection with FIG. 12, an inductor can be formed in the first TSV 1009. It will be appreciated that in one or more embodiments, the electromigration current limit is affected by the size, material, and temperature of the TSV's metallic conductor. Further, in one or more embodiments, the magnetic current limit is affected by the size, geometry, and magnetic properties of the magnetic material surrounding the TSV's metallic conductor. These properties determine when the magnetic field density reaches the saturation limit for the magnetic material. Utilizing analysis tools known in the art, such as a multifield finite element analysis using ANSYS® software (registered mark of ANSYS, Inc. Canonsburg PA USA), or other known programs, variables of the first TSV 1009 design can be evaluated by the skilled artisan, given the teachings herein. Utilizing such tools, the layout of the first TSV 1009 can be determined by the skilled artisan, given the teachings herein. As such, in some embodiments, the first TSV 1009 can be approximately 50 μm thick, as opposed to a thickness of 20-30 μm of previous approaches. The greater thickness of the first TSV 1009 can yield a proportional increase in unilateral current flow through the semiconductor structure per unit area (i.e., area density improvement). The current carrying ability of the first TSV 1009 can be, for example, at least 100 mA, per first TSV 1009.

In some embodiments, the first TSV 1009 can include the magnetic material. For example, the magnetic material can include co-fired ferrite, Lead-Dioxide (PbO₂), Beryllium-Oxide (BeO), Strontium-Oxide (SrO), Cobalt (Co), Manganese (Mn), BeO ferric, SrO ferrite, Cobalt-Oxide (CoO) ferrite, or any combination thereof. Further, the inductor can include magnetic material. The greater thickness of the first TSV 1009 can allow for more space for the magnetic material, improving function and efficiency, as described further herein.

In some embodiments, a second TSV 1011 can also be formed in the substrate 1001, as further shown in FIG. 3. The first TSV 1009 and the second TSV 1011 can be formed at the first side 1003 of the substrate 1001 and can extend into the substrate 1001. The first TSV 1009 can be formed proximate to the IVR 1007. FIG. 3 illustrates two first TSVs 1009 and one second TSV 1011, though examples are not so limited and one or multiple first TSVs 1009 and one or multiple second TSVs 1011 can be formed in the substrate 1001.

The second TSV 1011 can be a signal TSV. In some embodiments, the second TSV 1011 can have a coaxial structure, though examples are not so limited. The second TSV 1011 can have a different structure than the first TSV 1009. That is, the first TSV 1009 can include a first dielectric and a first metal (not shown) and the second TSV 1011 can include a second dielectric and a second metal (not shown). In some embodiments, the second TSV 1011 can include a thicker dielectric, a thinner metal, or both, than the first TSV 1009. The first dielectric of the first TSV 1009 and the second dielectric of the second TSV 1011 can include Silicon-Dioxide, Silicon-Nitride, Silicon-Oxynitride, Boron-Nitrited, Aluminum-Nitride, Beryllium-Oxide, Diamond-Film, Polymer, or any combination thereof. Further, the second TSV 1011 can include a non-magnetic via including a non-magnetic material, as opposed to the first TSV 1009 which can include a magnetic via having a surrounding magnetic material.

Further, as the first TSV 1009 is formed for carrying current unidirectionally between the IVR 1007, the capacitor 1023 (as illustrated in FIGS. 1 and 9-11), and the wiring layer 1021 (as illustrated in FIGS. 1, and 8-11), the diameter of the first TSV 1009 can be greater than the diameter of the second TSV 1011.

Further, as shown in FIG. 4, a dielectric layer 1015 can be formed on the first side 1003 of the substrate 1001. The skilled artisan can select appropriate dielectrics of known dielectric materials based on the description herein (if desired, different dielectrics can be chosen to surround power versus signal vias). An electrical connector 1013 can be formed within the dielectric layer 1015. The electrical connector 1013 can be electrically connected to the first TSV 1009, the second TSV 1011, and/or the IVR 1007.

Turning now to FIG. 5, electrical conductors 1017 can be attached to the dielectric layer 1015. In some embodiments, electrical conductors 1017 can be a controlled collapse chip connection (C4), such as a solder ball or bump or can be a bumpless Copper (Cu) bond, though examples are not so limited. Further, the electrical connectors 1013 can electrically connect the electrical conductors 1017 to the devices in the substrate 1001 (e.g., the first TSV 1009, the second TSV 1011, the IVR 1007, etc.). Forming the IVR 1007 in the substrate 1001 and proximate to the first TSV 1009 can allow for forming of the electrical conductors 1017 at a fine pitch (e.g., below 100 microns or more specifically, below 75 microns in some embodiments) between each electrical conductor (e.g., bump, ball, Copper bond) (that is, can enable formation of a finer pitch between each electrical conductor than previous approaches). Fine pitch electrical conductors 1017 can allow for an input that can be spread over a wide area of the dielectric layer 1015, improving accuracy of a voltage supplied, when compared to a voltage target, due to a reduction in current crowding through parasitics. It should be noted that a mixed pitch on the same part is possible in some embodiments; for example, where some interconnections are <75 microns and some are, for example, standard 150 or 130 micron pitch. Thus, generally, some embodiments can have mixed pitch with at least some I/O at a small pitch while not all I/O need be at this small pitch.

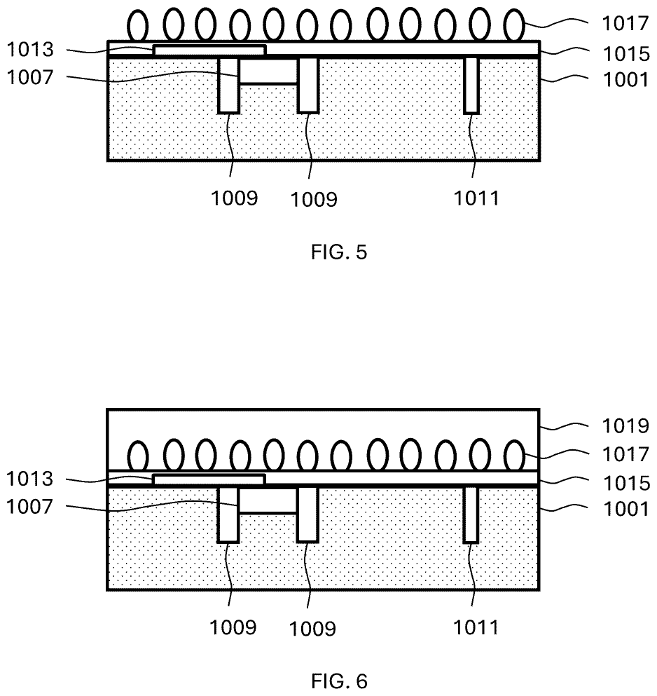

FIG. 6 illustrates, in simplified form, a temporary carrier bonded to the electric conductors 1017. In the example, element 1019 represents both an adhesive (e.g., temporary adhesive to planarize the solder blobs and bond the temporary carrier), and the carrier itself. Note that solder blobs are a non-limiting example of electrical conductors 1017 (as discussed further just below). In one example bonding process, facing surfaces are cleaned prior to bonding of the temporary carrier 1019. Note that after the temporary adhesive and carrier are removed, there can be a re-fill around the conductors 1017 as appropriate, in the final structure.

In addition to the use of solder blobs as electrical conductors in a final structure, hybrid bonding and the like can be employed. In the case of hybrid bonding, a permanent bond can combine a dielectric bond (e.g., SiOₓ) with embedded metal (e.g., Cu) to form interconnections (electrical conductors as alternatives to solder blobs). Two dies, interconnect structures, or semiconductor builds are joined together (e.g., two dies, semiconductor builds, or individual wafers that are built separately). They typically require a “pristine” surface (smooth and flat, possibly with some recesses), more so than traditional chemical-mechanical planarization (CMP). The two semiconductor builds are purposely designed to align. The term “hybrid” refers to the presence of both copper and dielectric. A bond that uses dielectric alone is referred to as fusion bonding (oxide to oxide, polymer to polymer, etc.). Hybrid bonding can use metal to metal connections for the copper. Two dies, interconnect structures or semiconductor builds are brought together facing each other and a small heat treatment/annealing process is carried out. The oxides bond together and the metals “anneal,” or almost melt, together, thus fusing the interface into a single bonded part (in some instances, seamlessly; i.e., the interface line disappears). Some embodiments can include a Cu—Cu bond, a Cu-Oxide bond, or when polymers are used can be a Cu-Polymer bond, though examples are not so limited.

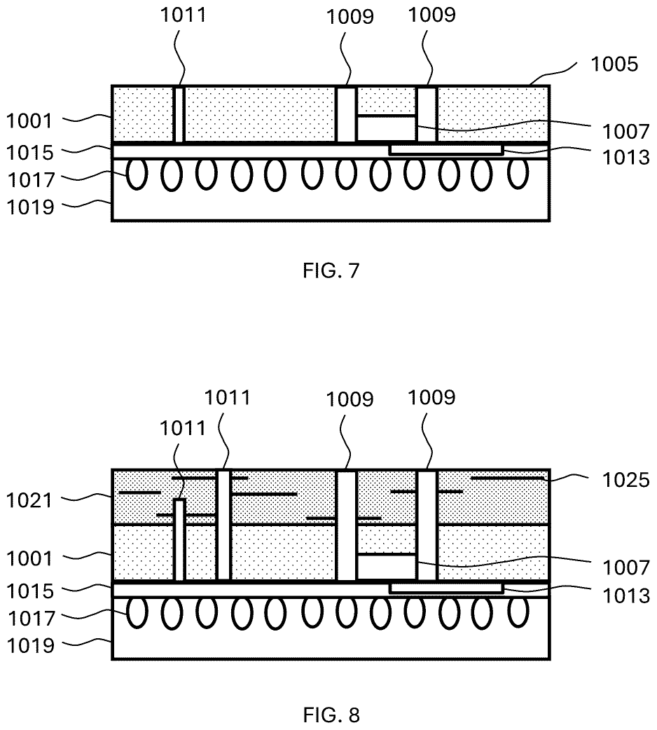

FIG. 7 illustrates flipping over the substrate 1001 and the temporary carrier 1019 and recessing a second side 1005 of the substrate 1001 down to and exposing the first TSV 1009. Further, in embodiments that include the second TSV 1011, the second side 1005 of the substrate 1001 can be recessed down to and can expose the second TSV 1011. The substrate 1001 can be recessed by grinding the substrate 1001, planarizing the substrate 1001, etching the substrate 1001, or any other suitable and/or preferred method. Etching the substrate 1001 can include a wet etch, though examples are not so limited. Though flipping of the semiconductor structure is illustrated, other processes are contemplated and thus, the disclosure is not so limiting.

As illustrated in FIG. 8, a wiring layer 1021 (e.g., back-end-of-line (BEOL) wiring layer) can be formed on the recessed second side 1005 of the substrate 1001. The wiring layer 1021 can be formed opposite the IVR 1007 and the dielectric layer 1015. A wiring layer 1021, for example a BEOL wiring layer, typically includes an insulative material, such as an oxide or other dielectric material, and various wiring layers which are well known to those skilled in the art. Further, the first TSV 1009 can be extended into the wiring layer 1021. In some embodiments, the first TSV 1009 can be extended through the wiring layer 1021. Additionally, redistribution layer (RDL) 1025 wiring can be formed within the wiring layer 1021. The RDL 1025 can include an insulating layer and vertical interconnects (e.g., conductive vias) formed in the insulating layer. The RDL 1025 wiring can be formed using techniques known in the art (e.g., techniques used for polymer deposition). RDL 1025 wiring can include one or more layers of wires or routing. The routing can include copper wiring or another suitable electrical conductor wiring. Preferably, the first TSV 1009 can be joined to the wiring layer 1021 in a single step, though examples are not so limited.

Further, in embodiments that include a second TSV 1011, the second TSV 1011 can be extended into the wiring layer 1021. In some embodiments, the second TSV 1011 can be extended through the wiring layer 1021. In still further embodiments, a second TSV 1011 can be formed from the first side 1003 of the substrate 1001 into or through the wiring layer 1021 after the substrate 1001 has been recessed. That is, a first portion of the second TSV 1011 can be formed, as previously illustrated in FIG. 3, prior to the formation of the wiring layer 1021 or the entire second TSV 1011 can be formed in conjunction with the formation of the wiring layer 1021. As such, the second TSV 1011 can be formed at the beginning of the process (e.g., in a first step), in the middle of the process/during the process, or at the end of the process (e.g., in a last step), depending on the method of fabrication of the semiconductor structure. TSVs of different pitch/dimensions can be formed at different stages, for example. Further, in some embodiments, a cavity can be formed in the semiconductor structure (e.g., in the substrate 1001, wiring layer 1021, etc.) and a bundle of second TSVs 1011 (e.g., such as fine pitch, small diameter TSVs) can be associated with the cavity. Such bundles can yield improved pitch control and thus improved conduit at differing speeds. As such, in some embodiments, a dense array of second TSV 1011 signal interconnects can be formed.

In some embodiments, a plurality of second TSVs 1011 can be formed. In some embodiments, the second TSVs 1011 can extend into the wiring layer 1021, can extend through the wiring layer 1021, or, as shown in FIG. 8, can be a combination thereof. That is, one second TSV 1011 can extend, at least partially, into the wiring layer 1021 and another second TSV 1011 can extend through (i.e., from one side to an opposite side) the wiring layer 1021. Additionally, one or all second TSVs 1011 can be formed prior to formation of the wiring layer 1021 and one or all second TSVs 1011 can be formed in conjunction with the formation of the wiring layer 1021, though examples are not so limiting.

Connections between the IVR 1007 and the first TSV 1009 can be formed. For example, the first TSV 1009 can include an inductor (L1, L2, as shown in FIG. 12 and further described herein.) formed in the first TSV 1009. The inductor can include magnetic material. In some embodiments, the inductor of the first TSV 1009 can be connected to the IVR 1007 by the wiring layer 1021. In still further embodiments, the inductor of the first TSV 1009 can be connected to the IVR 1007 at a side wall of the first TSV 1009 by a so-called “skim-by” connection. That is, by a metal-to-metal connection of the IVR 1007 either directly to a side wall of the first TSV 1009 or to a ledge formed in the side wall of the first TSV 1009. Given the teachings herein, the skilled artisan can adapt known processes for electrically connecting to through silicon vias, such as are described in publications on methods of making 3D integrated circuits, to implement one or more embodiments.

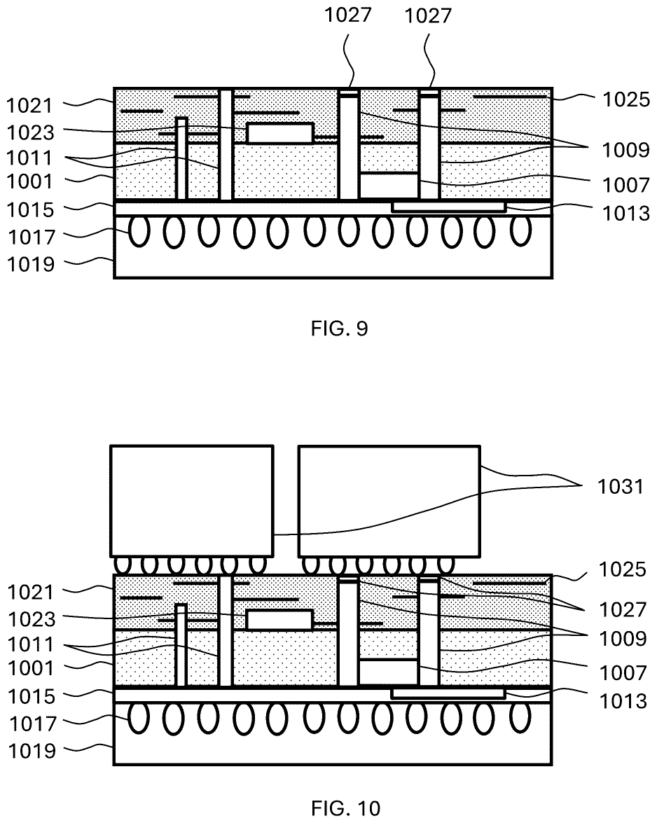

Further, as illustrated in FIG. 9, a capacitor 1023 can be formed in the semiconductor structure. In some embodiments the capacitor 1023 can be an integrated stacked capacitor (ISC) or a metal-insulator-metal (MIM) capacitor formed in the wiring layer 1021, though embodiments are not so limited. A MIM capacitor 1023 can be formed with an insulating layer (e.g., a dielectric layer) disposed between two metal plates. In some nonlimiting embodiments, the capacitor dielectric can be parallel to a surface of the substrate 1001, the top capacitor metal plate can be formed by a planar deposition of a conductive material (e.g., materials known to the skilled artisan to be capable of being lithographically patterned and etched using an RIE process), and the patterning of the top metal plate can include the use of a mask. Connections between the capacitor 1023 (e.g., MIM capacitor 1023) and the inductor of the first TSV 1009 can be formed. FIG. 9 illustrates a single capacitor 1023; however, multiple capacitors can be contemplated. Incorporating a MIM capacitor 1023 into the wiring layer 1021 can provide several advantages, such as saving space for other packaging features (e.g., deep trench capacitors), reducing signal blockage from the integrated circuit (IC) 1031, and the first TSV 1009 can be coupled or directly attached to the MIM capacitor 1023 allowing for a shorter distance between the two for communicating with each other increasing efficiency. Though not shown, in some embodiments deep trench (DT) capacitors can also be formed in the substrate 1001 and/or the wiring layer 1021.

In some embodiments, a termination 1027 can be formed on the first TSV 1009 for connection to an integrated circuit (IC) (e.g., IC 1031 as shown in FIG. 10). As illustrated in FIG. 10, an integrated circuit (IC) 1031 can be joined to the wiring layer 1021. Connections between the IC 1031 and the capacitor 1023 can be formed.

In some embodiments, the IVR 1007 can be located opposite the IC 1031. That is, the IVR 1007 can be located in a shadow of the IC 1031, though examples are not so limiting. In some examples, more than one IC 1031 can be attached to the wiring layer 1021. FIG. 10 illustrates two ICs 1031, one IC 1031 illustrating the IVR 1007 in the shadow or opposite the IC 1031 and the other IC 1031 illustrating optional connections to the second TSV 1011 (i.e., signal TSV 1011). As a note, second TSVs 1011 that stop in the wiring layer 1021 can get routed by wiring to the IC 1031. Optionally, the IC 1031 can be underfilled and/or over-molded (not shown) utilizing techniques known in the art.

The IVR 1007 can generate heat during operation of the semiconductor structure. In some scenarios, the IC 1031 can be sensitive to such temperature increases. Advantageously, in some embodiments, as previously described, the IVR 1007 can be formed in the substrate 1001 and the first TSV 1009 can be formed in the substrate 1001 proximate to the IVR 1007 and extend through the substrate 1001, RDL 1025, and wiring layer 1021 to the IC 1031. A portion of the heat created by operation of the IVR 1007 can be dissipated throughout the substrate 1001, allowing for protection of other devices, such as the IC 1031, from increasing temperatures. Additionally, the location of the IVR 1007 in relation to the IC 1031 (i.e., distance between the IVR 1007 and the IC 1031), that is, the IVR 1007 being formed at a first side of the substrate 1001 and the IC 1031 being joined to the wiring layer 1021 located at a second side of the substrate 1001 opposite the first side, can allow for additional protection of the IC 1031 from heat created by operation of the IVR 1007. Further, still, a heat sink (not shown) can be located on the IC 1031 or under the input power source 1033 and can further dissipate heat, protecting devices within the semiconductor structure.

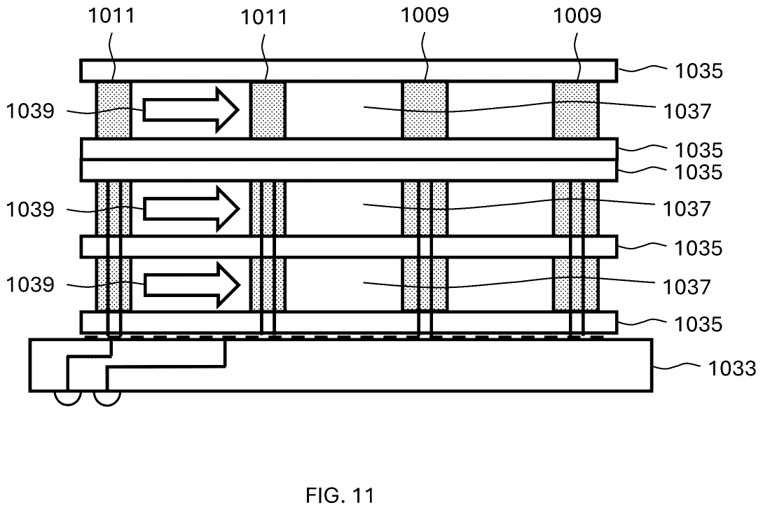

Turning now to FIG. 11, in some embodiments, a semiconductor structure can include thermal (utility) layers and a top layer, all designated as 1035. Cooling microchannels 1037 can be located between the layers 1035. FIG. 11 is a non-limiting example and other embodiments can have different numbers of layers and/or microchannels. In some embodiments, a first TSV 1009 and/or a second TSV 1011 can be located within posts that can traverse both the layers 1035 and the cooling microchannels 1037. In some embodiments, fluid can flow through the cooling microchannels 1037 (as indicated by the arrows 1039 shown in FIG. 11), drawing heat away from the posts and, accordingly, away from the first TSV 1009 and/or the second TSV 1011. In some embodiments, the TSVs can be power TSVs. generally, aspects of the invention can be employed in many different types of layers in a semiconductor structure. Fluid inlets and outlets, ductwork, a fluid mover such as a pump, fan, blower, etc. can all be provided as appropriate.

Turning back to FIG. 1, the temporary carrier 1019 can be removed. In one nonlimiting example, the temporary carrier 1019 can be debonded from the dielectric layer 1015 utilizing laser energy such as a UV laser or a Mid-IR laser. Once removed, the dielectric layer 1015 and electric conductors 1017 can be cleaned using techniques known in the art.

In some embodiments, multiple structures can be formed on a single substrate 1001.

Preceding debonding of the temporary carrier 1019, the structures can be diced, or singulated. The dielectric layer 1015 of a singulated structure can then be joined to an input power source 1033. For example, the input power source 1033 can be a final packaging substrate, though examples are not so limited. Accordingly, in some embodiments, the RDL 1025, the wiring layer 1021, the capacitor 1023, the substrate 1001, the first TSV 1009, the second TSV 1011, the IVR 1007, and the dielectric layer 1015 including the electrical connector 1013 can make up an interposer structure 1029. The interposer structure 1029 can be coupled to or joined to the input power source (e.g., package substrate) 1033 by the electrical conductors 1017. For example, the interposer structure 1029 can be coupled or joined to the input power source 1033 by reflow of solder balls or bumps or by bumpless Cu bonds that make up the electrical conductors 1017. Thus, the interposer structure 1029 can be sandwiched between the input power source 1033 and the IC 1031. As such, the semiconductor structure 1000 can include the IC 1031, the interposer structure 1029, and the input power source 1033.

Turning now to FIG. 12, a schematic diagram of a connection between the input power source 1033, the IVR 1007, the first TSV 1009, the wiring layer 1021, the capacitor 1023, and the IC 1031 is illustrated.

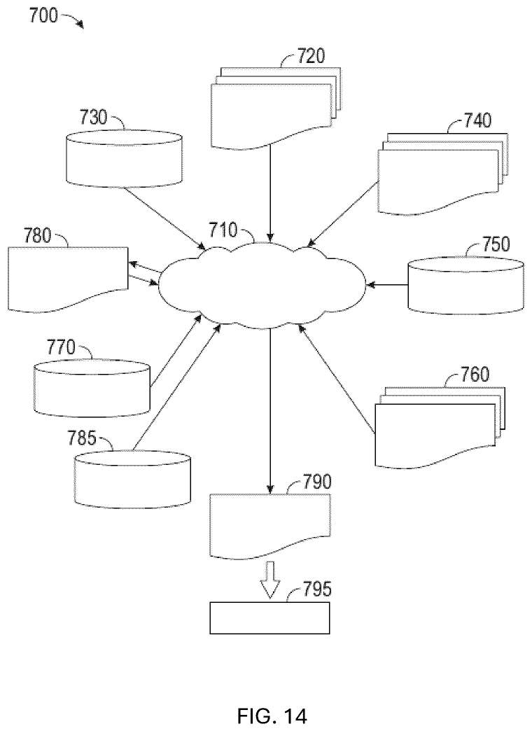

The IVR 1007 can include a controller. In some embodiments the controller can be a multiphase controller, as shown in FIG. 12, though examples are not so limited and in some embodiments the controller can be a single phase. The IVR 1007 can be a step-down (i.e., reduces voltage supplied from the input power source 1033) buck converter including field-effect transistors (FETs), though examples are not so limited and various converters known to the artisan can be contemplated. For example, in some embodiments, different types of logic can be used and can include switching capacitors, diodes, additional FETs, etc. In some embodiments, the IVR 1007 can be a low dropout linear regulator (LDO). The skilled artisan will be familiar with integrated circuits using field effect transistors (FETs). The skilled artisan can synthesize the controller, given the teachings herein, using techniques such as are described below with regard to FIG. 14. Also, note that a single connection is shown from VOUT to element 1031, but one or more embodiments will include a return current connection/ground, omitted to avoid clutter.

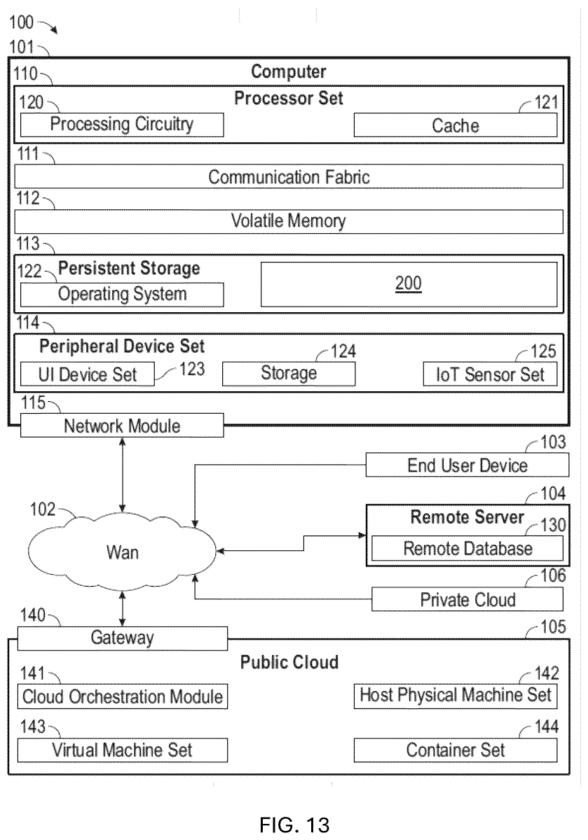

Given the teachings herein, the skilled artisan will be able to provide controller shown in FIG. 12 by adapting known techniques (e.g., in digital circuitry). To implement digital circuitry, computer-aided semiconductor integrated circuit (IC) logic design, simulation, test, layout, and/or manufacture can be employed, as discussed below with respect to FIG. 13. The skilled artisan can synthesize digital logic circuits to carry out desired control and other functionality, using known computer-aided design techniques. The controller carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture.

The gates of the FETs (Q1, Q2, Q3, and Q4 as shown in FIG. 12) can be coupled to the controller and a V_{IN} of the FETS (Q1 and Q3 as shown in FIG. 12) can be coupled to the input power source 1033 via the electrical conductors 1017. In some embodiments, the IVR 1007 can include four FETs, two sets of two as shown in FIG. 12, though examples are not so limited and fewer or greater than four FETs can be contemplated. Each FET output of each set of FETS, shown in FIG. 12, can be coupled together and connected to an inductor formed in the first TSV 1009. For example, an output to a first FET Q1 and an output to a second FET Q2 can be coupled at a Phase 1 Node and connected to a first inductor L1 of the first TSV 1009. Further, an output of a third FET Q3 and an output of a fourth FET Q4 can be coupled at a Phase 2 Node and connected to a second inductor L2 of the first TSV 1009. The first inductor L1 and the second inductor L2 can be coupled to the wiring layer 1021 and can further be coupled to a first end of the capacitor 1023 located in the wiring layer 1021. The first end of the capacitor 1023 can also be coupled to the IC 1031 via a V_{OUT} connection. A second end of the capacitor 1023 can be coupled to ground.

In some embodiments, voltage can be supplied at the V_{IN}, and the gate of the first FET Q1 can be toggled “on” by the controller to provide an increase in energy through the first inductor L1 raising current supplied. Further, the gate of the second FET Q2 can be toggled “on” causing a coast or drift of the IVR 1007, with a minimal increase in the current supplied during the rest of the cycle of the IVR 1007. That is, toggling “on” the first FET Q1 can increase a triangle wave of current while toggling “on” the second FET Q2 can decrease the triangle wave of current. Accordingly, the triangle wave of current can travel from the input power source 1033, through the electrical conductors 1017 through the first FET Q1, the second FET Q2, and the first inductor L1 of the first TSV 1009, increasing and decreasing dependent upon toggling “on” and “off” of the first FET Q1 and the second FET Q2. In some embodiments, the area density (as previously described) of the first TSV 1009 can support an input current of at least 100 mA per first TSV 1009. In further embodiments, the electrical conductors 1017 can support an input current up to 2 A and each first TSV 1009 can support an input current of greater than 100 mA.

Regulation of voltage and current by a buck IVR, such as IVR 1007, in combination with an inductor, such as first inductor L1, is well known in the art. As current starts to flow through the first FET Q1 (i.e., the gate to first FET Q1 is closed or “on”) current will begin to increase and in response to the change in current, the first inductor L1 will produce an opposing voltage across the terminals of the first inductor L1, counteracting voltage supplied and reducing net voltage to the IC 1031. As a rate of change of the current decreases, voltage across the first inductor L1 will also decrease, thus increasing net voltage to the IC 1031. Toggling FET Q1 open or “off” while the current is still changing will result in a voltage drop across the first inductor L1 and net voltage to the IC 1031 remaining less than the input voltage.

The first inductor L1 will store energy in the form of a magnetic field. When current ceases to flow through the first FET Q1 (i.e., the gate to first FET Q1 is opened or “off”) the voltage source will be removed from the semiconductor device, current will decrease, and voltage across the first inductor L1 will decrease. The first inductor L1 will become a current source as the stored energy from the first inductor's L1's magnetic field supports the current flow. In some embodiments, the first inductor L1 can be a magnetic inductor including any of the above-mentioned magnetic materials, co-fired ferrite, Lead-Dioxide (PbO₂), Beryllium-Oxide (BeO), Strontium-Oxide (SrO), Cobalt (Co), Manganese (Mn), BeO ferric, SrO ferrite, Cobalt-Oxide (CoO) ferrite, or any combination thereof. Magnetic materials can yield an increase in inductance. The increased thickness of the first TSV 1009, as opposed to previous approaches, or an increase in size (e.g., length) of the inductor L1, further increases the inductance of the first inductor L1. A larger inductor combined with the utilization of magnetic materials can result in an improvement in the efficiency of the IVR 1007. For example, in some embodiments, the first TSV 1009 can have a current carrying capability of up to and greater than 100 mA per first TSV 1009, as opposed to previous approaches.

The controller can toggle the first FET Q1 and the second FET Q2 gates with a timing that depends upon a target output voltage. Thus, as previously stated, the first FET Q1 can be toggled “on” to provide more energy through the first inductor L1 and raise the voltage and the second FET Q2 can be toggled “on” to coast and drift and raise the voltage a minimal amount during the rest of a cycle. As the first FET Q1 and the second FET Q2 are toggled “on” and “off” pulses of current are sent to the IC 1031. Such pulses can cause noise. One way to reduce such noise is to provide for additional devices, such as the third FET Q3, the fourth FET Q4, and the second inductor L2. That is, providing for a multiphase controller. For example, 360 degrees can define the repetitive phase of the cycle. If the IVR 1007 includes two devices, that is first FET Q1, second FET Q2, and first inductor L1 as device number one and third FET Q3, fourth FET Q4, and second inductor L2 as device number two, and the two devices insert pulses half as big, twice as often, then the same current can be supplied with less ripple, but using the same amount of capacitance. Thus, in some embodiments, as shown in FIG. 12, the third FET Q3, fourth FET Q4, and second inductor L2 can operate in the same way as the first FET Q1, second FET Q2, and first inductor L1, respectively. Ideally, in this embodiment, the second inductor L2 will be approximately 180 degrees out of phase from the first inductor L1.

Turning back to FIG. 12, the triangle wave of current can further travel from the first inductor L1 and/or second inductor L2 through the capacitor 1023 to the IC 1031. The capacitor 1023 can even out (i.e., reduce an amplitude of) voltage spikes that can occur from the switching “on” and “off” of FETs Q1, Q2, Q3, and/or Q4, providing stability in the energy supplied to the IC 1031.

In some embodiments, current can return to the input power source 1033. That is, the semiconductor structure can further include connections for a return path of the ground, forming a loop. As a charge will not build up unilaterally, the charge will return at a lower voltage as energy has been taken or consumed. As such, the input power source 1033 can provide a first amount of voltage as an input to the IVR 1007 and the IC 1031 can return a second amount of voltage lower than the first amount of voltage. Thus, current can unidirectionally flow between the input power source 1033 and the IC 1031 through the IVR 1007, the first TSV 1009, and the capacitor 1023 with minimal noise (i.e., an increased stability and non-varying voltage regulated by the controller) and increased efficiency. Note, so as not to obfuscate the drawings, FIG. 12 illustrates only one connection to the IC 1031; however multiple connections, including a return path (e.g., return current connection, ground connection, other signal connections, etc.) to and from the IC 1031 are contemplated. Accordingly, to avoid excessive clutter, the current return path has been omitted.

Reference should now be had to FIG. 13, which illustrates a computing environment according to an embodiment of the present invention (e.g., for implementing a design process such as that of FIG. 14 to synthesize the controller, other circuitry, or the like).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks can be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium can be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random-access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 13). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 can take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method can be distributed among multiple computers and/or between multiple locations. On the other hand, in this presentation of computing environment 100, detailed discussion is focused on a single computer, specifically computer 101, to keep the presentation as simple as possible. Computer 101 can be located in a cloud, even though it is not shown in a cloud in FIG. 13. On the other hand, computer 101 is not required to be in a cloud except to any extent as can be affirmatively indicated.

PROCESSOR SET 110 includes one, or more, computer processors of any type now known or to be developed in the future. Processing circuitry 120 can be distributed over multiple packages, for example, multiple, coordinated integrated circuit chips. Processing circuitry 120 can implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set can be located “off chip.” In some computing environments, processor set 110 can be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods can be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports, and the like. Other types of signal communication paths can be used, such as fiber optic communication paths and/or wireless communication paths.

VOLATILE MEMORY 112 is any type of volatile memory now known or to be developed in the future. Examples include dynamic type random-access memory (RAM) or static type RAM. Typically, volatile memory 112 is characterized by random-access, but this is not required unless affirmatively indicated. In computer 101, the volatile memory 112 is located in a single package and is internal to computer 101, but, alternatively or additionally, the volatile memory can be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 can be a read only memory (ROM), but typically at least a portion of the persistent storage allows writing of data, deletion of data, and re-writing of data. Some familiar forms of persistent storage include magnetic disks and solid state storage devices. Operating system 122 can take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 can be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 can include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 can be persistent and/or volatile. In some embodiments, storage 124 can take the form of a quantum computing storage device for storing data in the form of qubits. In embodiments where computer 101 is required to have a large amount of storage (for example, where computer 101 locally stores and manages a large database) then this storage can be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor can be a thermometer and another sensor can be a motion detector.

NETWORK MODULE 115 is the collection of computer software, hardware, and firmware that allows computer 101 to communicate with other computers through WAN 102. Network module 115 can include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 can be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and can take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 can be a client device, such as thin client, heavy client, mainframe computer, desktop computer, and so on.

REMOTE SERVER 104 is any computer system that serves at least some data and/or functionality to computer 101. Remote server 104 can be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data can be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs can be stored as images and can be transferred among and between the various physical machine hosts, either as images or after instantiation of the VCE. Cloud orchestration module 141 manages the transfer and storage of images, deploys new instantiations of VCEs, and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is illustrated as being in communication with WAN 102, in other embodiments a private cloud can be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 14 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines can include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 700 can vary depending on the type of representation being designed. For example, a design flow 700 for building an application specific IC (ASIC) can differ from a design flow 700 for designing a standard component or from a design flow 700 for instantiating the design into a programmable array, for example a programmable gate array (PGA) or a field programmable gate array (FPGA) offered by Altera® Inc, or Xilinx® Inc.

FIG. 14 illustrates multiple such design structures including an input design structure 720 that is preferably processed by a design process 710. Design structure 720 can be a logical simulation design structure generated and processed by design process 710 to produce a logically equivalent functional representation of a hardware device. Design structure 720 can also or alternatively comprise data and/or program instructions that when processed by design process 710, generate a functional representation of the physical structure of a hardware device. Whether representing functional and/or structural design features, design structure 720 can be generated using electronic computer-aided design (ECAD) such as implemented by a core developer/designer. When encoded on a gate array or storage medium or the like, design structure 720 can be accessed and processed by one or more hardware and/or software modules within design process 710 to simulate or otherwise functionally represent an electronic component, circuit, electronic or logic module, apparatus, device, or system. As such, design structure 720 can comprise files or other data structures including human and/or machine-readable source code, compiled structures, and computer executable code structures that when processed by a design or simulation data processing system, functionally simulate or otherwise represent circuits or other levels of hardware logic design. Such data structures can include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which can contain design structures such as design structure 720. Netlist 780 can comprise, for example, compiled or otherwise processed data structures representing a list of wires, discrete components, logic gates, control circuits, I/O devices, models, etc. that describes the connections to other elements and circuits in an integrated circuit design. Netlist 780 can be synthesized using an iterative process in which netlist 780 is resynthesized one or more times depending on design specifications and parameters for the device. As with other design structure types described herein, netlist 780 can be recorded on a machine-readable data storage medium or programmed into a programmable gate array. The medium can be a nonvolatile storage medium such as a magnetic or optical disk drive, a programmable gate array, a compact flash, or other flash memory. Additionally, or in the alternative, the medium can be a system or cache memory, buffer space, or other suitable memory.

Design process 710 may include hardware and software modules for processing a variety of input data structure types including Netlist 780. Such data structure types can reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types can further include design specifications 740, characterization data 750, verification data 760, design rules 770, and test data files 785 which can include input test patterns, output test results, and other testing information. Design process 710 can further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 can also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the illustrated supporting data structures along with any additional mechanical design or data (if applicable), to generate a second design structure 790. Design structure 790 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 can comprise a compiled, executable HDL simulation model that functionally simulates the devices to be analyzed.

Design structure 790 can also employ a data format used for the exchange of layout data of integrated circuits and/or symbolic data format (e.g., information stored in a GDSII (GDS2), GL1, OASIS, map files, or any other suitable format for storing such design data structures). Design structure 790 can comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 can then proceed to a stage 795 where, for example, design structure 790: proceeds to tape-out, is released to manufacturing, is released to a mask house, is sent to another design house, is sent back to the customer, etc.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching.” For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76 (b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
one or more integrated circuits (ICs);
a wiring layer coupled to the one or more ICs;
an input power source; and
a substrate located between the wiring layer and the input power source, the substrate comprising:
a first side coupled to the input power source;
a second side coupled to the wiring layer;
an integrated voltage regulator (IVR) located at the first side of the substrate; and
a first through-silicon-via (TSV) coupled to the IVR and extending through the substrate and into the wiring layer.

2. The semiconductor structure of claim 1, wherein the first TSV comprises a magnetic via including a surrounding magnetic material, wherein the surrounding magnetic material is selected from the group consisting of:
co-fired ferrite;
Lead-Dioxide (PbO₂);
Beryllium-Oxide (BeO);
Strontium-Oxide (SrO);
Cobalt (Co);
Manganese (Mn);
BeO ferric;
SrO ferrite;
Cobalt-Oxide (CoO) ferrite; and
any combination thereof.

3. The semiconductor structure of claim 1, further comprising thermal layers separated by a cooling microchannel, wherein the first TSV extends through the thermal layers and the cooling microchannel.

4. The semiconductor structure of claim 1, wherein the substrate comprises one or more first TSVs and at least one of the first TSVs comprises an inductor.

5. The semiconductor structure of claim 4, wherein the IVR is connected to the inductor of the first TSV by a skim-by-connection.

6. The semiconductor structure of claim 4, wherein the IVR is connected to the inductor of the first TSV by the wiring layer.

7. The semiconductor structure of claim 4, further comprising a capacitor coupled to the inductor of the first TSV.

8. The semiconductor structure of claim 1, further comprising a second TSV extending through the substrate into the wiring layer, wherein the second TSV is a signal TSV.

9. The semiconductor structure of claim 8, wherein the second TSV comprises a non-magnetic via including a non-magnetic material.

10. The semiconductor structure of claim 8, wherein the second TSV has a coaxial structure.

11. The semiconductor structure of claim 8, wherein:
the first TSV comprises a first dielectric and a first metal;
the second TSV comprises a second dielectric and a second metal; and
the second TSV comprises a thicker dielectric, a thinner metal, or both, than the first TSV.

12. The semiconductor structure of claim 11, wherein the first dielectric and the second dielectric are selected from the group consisting of:
Silicon-Dioxide;
Silicon-Nitride;
Silicon-Oxynitride;
Boron-Nitride;
Aluminum-Nitride;
Beryllium-Oxide;
Diamond-Film;
Polymer; and
any multilayer combination thereof.

13. The semiconductor structure of claim 8, wherein a diameter of the first TSV is greater than a diameter of the second TSV.

14. The semiconductor structure of claim 1, wherein the one or more ICs include at least two ICs and wherein the wiring layer and the substrate comprise an interposer.

15. The semiconductor structure of claim 14, further comprising electrical conductors, wherein the interposer is coupled to the input power source by the electrical conductors.

16. A method of forming a semiconductor structure, comprising:
forming, at a first side of a substrate, an integrated voltage regulator (IVR);
forming, proximate to the IVR, first through-silicon vias (TSVs) in the substrate;
forming, on the first side of the substrate, a dielectric layer comprising an electrical connector;
attaching electrical conductors to the dielectric layer, wherein the electrical connector in the dielectric layer electrically connects the electrical conductors to the substrate;
bonding a temporary carrier to the electrical conductors, flipping over the substrate and the temporary carrier, and recessing a second side of the substrate, exposing the first TSVs;
forming, on the recessed second side of the substrate, a wiring layer and a redistribution layer (RDL);
extending the first TSVs from the second side of the recessed substrate through the wiring layer;
forming a capacitor in the wiring layer;
joining to the wiring layer one or more integrated circuits (ICs);
removing the temporary carrier; and
joining to the dielectric layer, at the electrical conductors, an input power source.

17. The method of claim 16, further comprising forming a second TSV, wherein:
the second TSV is a signal TSV comprising a thicker dielectric, thinner metal, or both, than the first TSVs; and
the first TSVs are formed with a diameter larger than the second TSV.

18. The method of claim 17, wherein the second TSV extends from the dielectric layer, through the substrate and at least partially into the wiring layer or through the wiring layer to the RDL.

19. The method of claim 16, further comprising forming an inductor in each of the first TSVs and connecting the IVR to the inductor of a first TSV with a skim-by-connection on a sidewall of the first TSV or at the wiring layer.

20. The method of claim 19, further comprising forming a connection between the capacitor and the inductor in each of the first TSVs and forming a connection between the capacitor and the one or more ICs.
